(19) United States
(12) Patent Application Publication
(10) Pub. No.: US 2024/0011143 A1
(43) Pub. Date: Jan. 11, 2024

(54) MASK ASSEMBLY, APPARATUS FOR MANUFACTURING DISPLAY DEVICE INCLUDING THE SAME, METHOD OF MANUFACTURING DISPLAY DEVICE, AND METHOD OF MANUFACTURING MASK ASSEMBLY

(71) Applicant: Samsung Display Co., Ltd., Yongin-si (KR)

(72) Inventors: Areum Lee, Yongin-si (KR); Jeongkuk Kim, Yongin-si (KR); Hwi Kim, Yongin-si (KR); Youngmin Moon, Yongin-si (KR); Seungyong Song, Yongin-si (KR); Eunbee Jo, Yongin-si (KR); Kyuhwan Hwang, Yongin-si (KR)

(73) Assignee: Samsung Display Co., Ltd., Yongin-si (KR)

(21) Appl. No.: 18/347,792

(22) Filed: Jul. 6, 2023

(30) Foreign Application Priority Data
Jul. 11, 2022 (KR) 10-2022-0085269

(51) Int. Cl. C23C 14/04; H10K 71/16

(52) U.S. Cl. CPC C23C 14/042; H10K 71/166

(57) ABSTRACT

Provided are a mask assembly and a manufacturing method thereof, and an apparatus and a method of manufacturing a display device. The mask assembly includes a mask frame including an opening region, a support member disposed on the mask frame to divide the opening region into at least two, and a mask sheet disposed on the support member to overlap the opening region and including uneven edge portions and a plurality of holes.

### CROSS-REFERENCE TO RELATED APPLICATION(S)

This application claims priority to and benefits of Korean Patent Application No. 10-2022-0085269 under 35 U.S.C. § 119, filed on Jul. 11, 2022, in the Korean Intellectual Property Office, the entire contents of which are incorporated herein by reference.

### BACKGROUND

### 1. Technical Field

One or more embodiments relate to an apparatus and method, and specifically to a mask assembly, an apparatus for manufacturing a display device including the mask assembly, a method of manufacturing the display device, and a method of manufacturing the mask assembly.

### 2. Description of the Related Art

Mobile electronic devices have been widely used. In addition to small electronic devices, such as mobile phones, tablet personal computers (“PCs”) have recently been widely used as mobile electronic devices.

In order to implement various functions, the mobile electronic devices include a display device for providing a user with visual information, such as an image or video. Recently, as other parts for driving the display device have become smaller, a proportion of the display device in the electronic device has been gradually increasing, and a structure capable of being bent in a flat state to have a certain angle has also been being developed.

### SUMMARY

A display device may include a plurality of organic light-emitting diodes, and each organic light-emitting diode may include an organic layer. For example, apparatuses for forming organic layers respectively disposed in organic light-emitting diodes different from each other have been used. For example, resolution of the display device may be different according to how precisely the organic layers are deposited. For example, mask sheets of various sizes may be used to guide a deposition material to display areas of different sizes in various areas of a single substrate. One or more embodiments provide a mask assembly in which a deposition material is deposited in display areas of various sizes through a mask sheet fixed through a simple process, an apparatus for manufacturing a display device including the mask assembly, a method of manufacturing the display device, and a method of manufacturing the mask assembly.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a mask assembly may include a mask frame including an opening region, a support member disposed on the mask frame to divide the opening region into at least two, and a mask sheet disposed on the support member to overlap the opening region, and including uneven edge portions and a plurality of holes.

The mask sheet may be fixed to the support member in a tensioned state.

The support member may include a groove overlapping a protruding portion of the uneven edge portions of the mask sheet.

The groove may include a plurality of grooves spaced apart from each other.

The groove may have a line shape in a longitudinal direction of the support member.

A width of the protruding portion of the uneven edge portions of the mask sheet in a longitudinal direction of the support member may be smaller than a width of the groove in the support member in the longitudinal direction of the support member.

The mask sheet may be fixed to the support member by a welding process, wherein the support member may include a welding groove overlapping a welding point formed by the welding process and having a depth smaller than a depth of the groove.

The depth of the welding groove may be about 20% or less of a thickness of the support member.

The mask sheet may be fixed to the support member by a welding process, wherein a welding point formed during the welding process may be disposed on an inner side of the uneven edge portions of the mask sheet.

The support member may include a welding groove overlapping the welding point.

A depth of the welding groove may be about 20% or less of a thickness of the support member.

According to one or more embodiments, an apparatus for manufacturing a display device may include a chamber, a mask assembly overlapping a substrate disposed in the chamber, and a deposition source that supplies a deposition material to the substrate, wherein the mask assembly may be the mask assembly described above.

According to one or more embodiments, a method of manufacturing a mask assembly may include disposing and fixing a support member on a mask frame, disposing a mask sheet mother material on the support member in a tensioned state, fixing the mask sheet mother material to the support member by a welding process, and forming a mask sheet including edge portions in an uneven shape by a cutting process cutting a portion of the mask sheet mother material.

The mask sheet mother material may include: a body portion including a plurality of holes and disposed in a center portion of the mask sheet mother material, a wing portion protruding from the body portion, a plurality of incision portions disposed between the body portion and the wing portion, the plurality of incision portions spaced apart from each other and arranged along an edge portion of the body portion, and at least one rib portion disposed between the plurality of incision portions.

The support member may include a groove overlapping the at least one rib portion.

A width of the at least one rib portion in a direction perpendicular to a longitudinal direction of the at least one rib portion may be smaller than a width of the groove in the direction perpendicular to the longitudinal direction of the at least one rib portion.

The support member may include a groove overlapping at least a portion of the at least one rib portion in a plan view and having a closed loop shape.

The method may further include forming, in the support member, a welding groove overlapping a welding point at which the mask sheet mother material and the support member are welded to each other.

A depth of the welding groove may be about 20% or less of a thickness of the support member.

The welding process and the cutting process on the mask sheet mother material may be performed by using a same laser.

According to one or more embodiments, a method of manufacturing a display device may include disposing a substrate and a mask assembly in a chamber, and supplying a deposition material from a deposition source and depositing the deposition material on the substrate by passing through the mask assembly, wherein the mask assembly may be the mask assembly described above.

These general and specific embodiments may be implemented by using a system, a method, a computer program, or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a mask assembly according to an embodiment;

FIG. 2 is a schematic cross-sectional view of the mask assembly, taken along line A-A′ of FIG. 1;

FIGS. 3A, 3B, and 3C are schematic plan views of grooves shown in FIG. 1;

FIG. 4 is a schematic cross-sectional view of a portion of a mask assembly according to an embodiment;

FIG. 5 is a schematic front view of an apparatus for manufacturing a mask assembly according to an embodiment;

FIG. 6 is a schematic plan view of a method of manufacturing the mask assembly shown in FIG. 1;

FIG. 7 is a schematic cross-sectional view taken along line C-C′ of FIG. 6;

FIG. 8 is a schematic cross-sectional view of an apparatus for manufacturing a display device according to an embodiment;

FIG. 9 is a schematic plan view of a display device according to an embodiment;

FIG. 10 is a schematic cross-sectional view of the display device, taken along line X-X′ of FIG. 9; and

FIGS. 11A and 11B are schematic diagrams of equivalent circuits of a sub-pixel included in the display device shown in FIG. 9.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

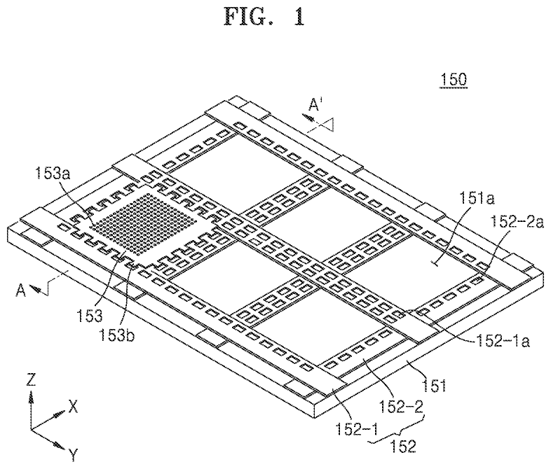

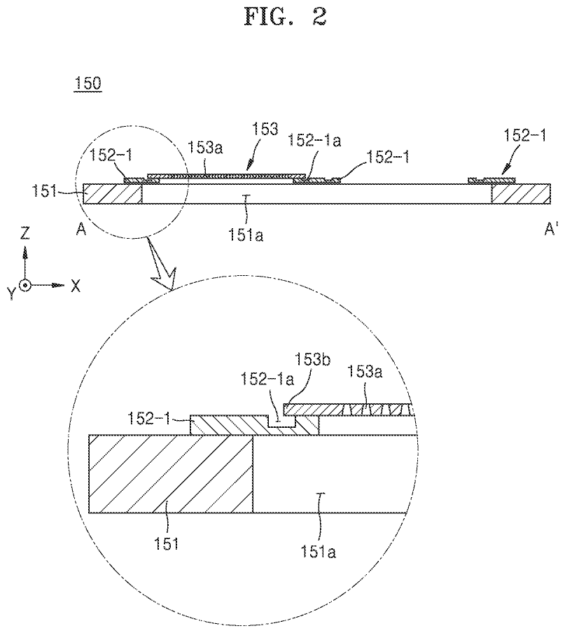

FIG. 1 is a schematic perspective view of a mask assembly 150 according to an embodiment. FIG. 2 is a schematic cross-sectional view of the mask assembly 150, taken along line A-A′ of FIG. 1.

Referring to FIGS. 1 and 2, the mask assembly 150 may include a mask frame 151, a support member 152, and a mask sheet 153.

The mask frame 151 may include frames connected to each other. For example, an opening region 151a may be arranged in a central portion of the mask frame 151.

The support member 152 may be disposed on the mask frame 151 to divide the opening region 151a into at least two. For example, the support member 152 may cross the opening region 151a, thereby supporting the mask sheet 153. The support member 152 may include a first support member 152-1 and a second support member 152-2 crossing each other. For example, the first support member 152-1 and the second support member 152-2 may have various shapes. For example, the first support member 152-1 and the second support member 152-2 may be integral with each other and be fixed on the mask frame 151. In another example, the first support member 152-1 and the second support member 152-2 may be separated from each other and cross each other. For example, respective end portions of the first support member 152-1 and the second support member 152-2 each disposed on the mask frame 151 may be fixed to the mask frame 151 by a welding process or the like. Hereinafter, a case in which the first support member 152-1 and the second support member 152-2 are separated from each other will be described for descriptive convenience.

The first support member 152-1 and the second support member 152-2 may be formed in a thin plate shape and cross each other. The first support member 152-1 and the second support member 152-2 may support the mask sheet 153. For example, the first support member 152-1 may extend to have a long side in a first direction (e.g., a Y-axis direction of FIG. 1). For example, the second support member 152-2 may extend to have a long side in a second direction (e.g., an X-axis direction of FIG. 2). The first support member 152-1 and the second support member 152-2 may cross each other, thereby dividing the opening region 151a into regions. For example, in an embodiment, a planar area of each region may be the same as each other. In another example, a planar area of one of regions may be different from a planar area of another of the regions. In another example, some of regions may have the same planar area as each other, and some of the regions may have different planar areas from each other. A planar shape of each region as described above may be different from each other. For example, a planar shape of one of regions may be a polygonal shape, and a planar shape of another of regions may be a circle. However, a case in which a planar shape of each of regions is a quadrangle and a planar area of each of regions is different from each other will be described below for convenience.

For example, the end portion of the first support member 152-1 and the end portion of the second support member 152-2 may be disposed on the mask frame 151. For example, the end portion of the first support member 152-1 and the end portion of the second support member 152-2 may be fixed to the mask frame 151 by a welding process or the like. For example, the first support member 152-1 and the second support member 152-2 may each be fixed on the mask frame 151 with tensile force applied in a longitudinal direction thereof.

The first support member 152-1 and the second support member 152-2 may include grooves corresponding to portions of the mask sheet 153. For example, the first support member 152-1 may include a first groove 152-la corresponding to a portion of the mask sheet 153. For example, the second support member 152-2 may include a second groove 152-2a corresponding to a portion of the mask sheet 153. For example, the first groove 152-la and the second groove 152-2a may include first grooves 152-la and second grooves 152-2a, respectively. For example, the first grooves 152-la may be spaced apart from each other in a longitudinal direction of the first support member 152-1, and the second grooves 152-2a may be spaced apart from each other in a longitudinal direction of the second support member 152-2.

The first support member 152-1 and the second support member 152-2 may include first support members 152-1 and second support members 152-2, respectively. For example, the first support members 152-1 may be spaced apart from each other in the second direction. For example, the second support members 152-2 may be spaced apart from each other in the first direction.

For example, arrangements of the first grooves 152-la in each first support member 152-1 may be different according to where each first support member 152-1 is arranged. For example, the first support member 152-1 close to a central portion of the opening region 151a may have the first grooves 152-la arranged in two columns. For example, the first support member 152-1 arranged at an outer portion of the opening region 151a may have the first grooves 152-la arranged in one column. For example, arrangements of the first grooves 152-la in each first support member 152-1 may vary according to the number of mask sheets 153 supported by each first support member 152-1.

Arrangements of the second grooves 152-2a in the second support member 152-2 may also be similar to those of the first grooves 152-1a. For example, the second support member 152-2 close to a central portion of the opening region 151a may have the second grooves 152-2a arranged in two columns. For example, the second support member 152-2 arranged at an outer portion of the opening region 151a may have the second grooves 152-2a arranged in one column. For example, arrangements of the second grooves 152-2a in each second support member 152-2 may vary according to the number of mask sheets 153 supported by each second support member 152-2.

For example, a top surface (or upper surface) of the mask frame 151 may be flat or may have an insertion groove in which the end portion of at least one of the first support member 152-1 and the second support member 152-2 to be inserted. Hereinafter, a case in which a top surface (or upper surface) of the mask frame 151 is flat will be described for descriptive convenience.

The mask sheet 153 may be arranged in one of regions in which the opening region 151a is divided by the first support member 152-1 and the second support member 152-2. For example, planar shapes and sizes of divided regions may be the same as each other. In another example, a planar shape and size of one of divided regions may be different from a planar shape and size of another of the divided regions. In another example, planar shapes and sizes of divided regions may all be different from each other. For example, the mask sheet 153 may have a planar shape (or a plate shape) and size corresponding to divided regions of the opening region 151a. For example, the mask sheet 153 may include mask sheets 153, and each mask sheet 153 may correspond to each region.

The mask sheet 153 may be disposed on the first support member 152-1 and the second support member 152-2 and be attached to the first support member 152-1 and the second support member 152-2. For example, the first support member 152-1 and the second support member 152-2 may function as a shield between mask sheets 153 adjacent to each other and may also support mask sheets 153 adjacent to each other.

The mask sheet 153 may include an opening 153a. For example, the opening 153a may include openings (or holes) 153a, and the openings 153a may be spaced apart from each other in at least one of the first direction and the second direction.

An edge portion of the mask sheet 153 may be uneven. For example, the mask sheet 153 may include a protrusion (or protruding portion) 153b where a part of an edge portion of the mask sheet 153 protrudes. For example, the protrusion 153b may correspond to (or overlap) the first groove 152-la or the second groove 152-2a.

The mask sheet 153 may be fixed on the first support member 152-1 and the second support member 152-2 and may be tensioned in the first direction and the second direction. For example, a method of fixing the mask sheet 153 may include fixing the mask sheet 153 on the first support member 152-1 and the second support member 152-2 by performing a welding process along the edge portion of the mask sheet 153.

The mask assembly 150 may provide firm fixation of the mask sheet 153 and may also reduce (or minimize) deformation of the mask sheet 153. For example, the mask assembly 150 may simultaneously guide a deposition material to display areas spaced apart from each other over a substrate.

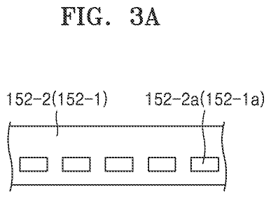

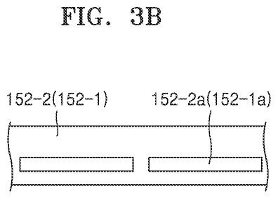

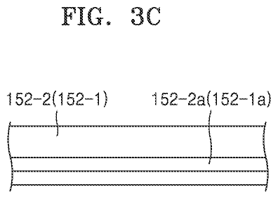

FIGS. 3A, 3B, and 3C are schematic plan views of grooves shown in FIG. 1.

Referring to FIGS. 3A to 3C, each of the first groove 152-la and the second groove 152-2a may have various planar shapes (e.g., a closed loop shape). For example, as shown in FIG. 3A, a planar shape of each of the first groove 152-la and the second groove 152-2a may be a quadrangular shape. For example, each first groove 152-la or each second groove 152-2a may overlap one protrusion 153b in a plan view.

In another example, as shown in FIG. 3B, a planar shape of at least one of the first groove 152-la and the second groove 152-2a may be a quadrangle. For example, the quadrangle may have a rectangular shape. For example, at least one of the first groove 152-la and the second groove 152-2a may overlap protrusions 153b in a plan view. For example, the first groove 152-la may extend to have a long side in a longitudinal direction of the first support member 152-1, and the second groove 152-2a may extend to have a long side in a longitudinal direction of the second support member 152-2.

In another example, as shown in FIG. 3C, a planar shape of at least one of the first groove 152-la and the second groove 152-2a may be a line shape. For example, the first groove 152-la may extend in a longitudinal direction of the first support member 152-1. For example, the second groove 152-2a may extend in a longitudinal direction of the second support member 152-2. For example, the first groove 152-la and the second groove 152-2a may be formed in different directions from each other. For example, all protrusions 153b arranged on a side of the mask sheet 153 may correspond to the first groove 152-la or the second groove 152-2a.

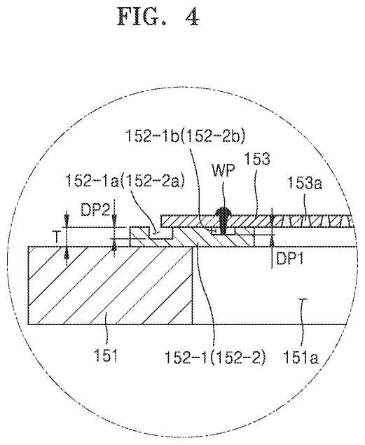

FIG. 4 is a schematic cross-sectional view of a portion of the mask assembly 150 according to an embodiment.

Referring to FIG. 4, the mask assembly 150 may include the mask frame 151, the support member 152, and the mask sheet 153. For example, the mask frame 151 and the mask sheet 153 are the same as or similar to those described above with reference to FIGS. 1 and 2, and thus, a detailed description thereof is omitted for descriptive convenience.

The support member 152 may include the first support member 152-1 and the second support member 152-2. For example, arrangements and fixing methods of the first support member 152-1 and the second support member 152-2 are the same as or similar to those described above, and thus, a detailed description thereof is omitted for descriptive convenience.

The first support member 152-1 may include a first welding groove 152-1b in addition to the first groove 152-1a. For example, a first depth DP1 of the first welding groove 152-1b may be different from a second depth DP2 of the first groove 152-1a. For example, the first depth DP1 of the first welding groove 152-1b may be smaller than the second depth DP2 of the first groove 152-1a. For example, the first depth DP1 of the first welding groove 152-1b may be about 20% or less of a thickness T of the first support member 152-1. The second depth DP2 of the first groove 152-la is greater than about 20% of the thickness T of the first support member 152-1. For example, in case that the first depth DP1 of the first welding groove 152-1b is greater than about 20% of the thickness T of the first support member 152-1, welding may not be properly performed, and thus, the first support member 152-1 and the mask sheet 153 may not be fixed to each other. For example, the thickness T of the first support member 152-1 may be measured in the same direction as a direction in which the first depth DP1 or the second depth DP2 may be measured, and may refer to a distance from one surface of the first support member 152-1 to the other surface.

The first welding groove 152-1b may be arranged in a line with the first groove 152-la in a second direction. In another example, the first welding groove 152-1b may alternate with the first groove 152-1a. For example, the first welding groove 152-1b may be arranged between first grooves 152-la adjacent to each other. Hereinafter, a case in which the first welding groove 152-1b is arranged in a line with the first groove 152-la in a second direction will be described for descriptive convenience.

The second support member 152-2 may include the second groove 152-2a and a second welding groove 152-2b. For example, the second groove 152-2a and the second welding groove 152-2b may be similar to the first groove 152-la and the first welding groove 152-1b described above.

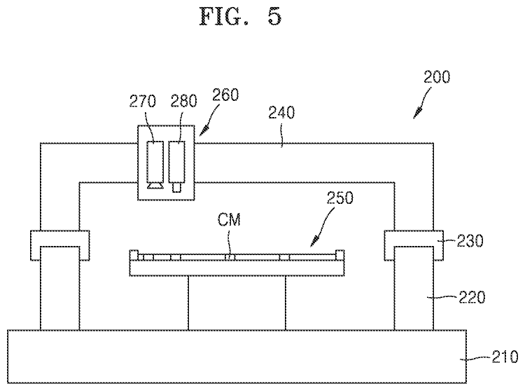

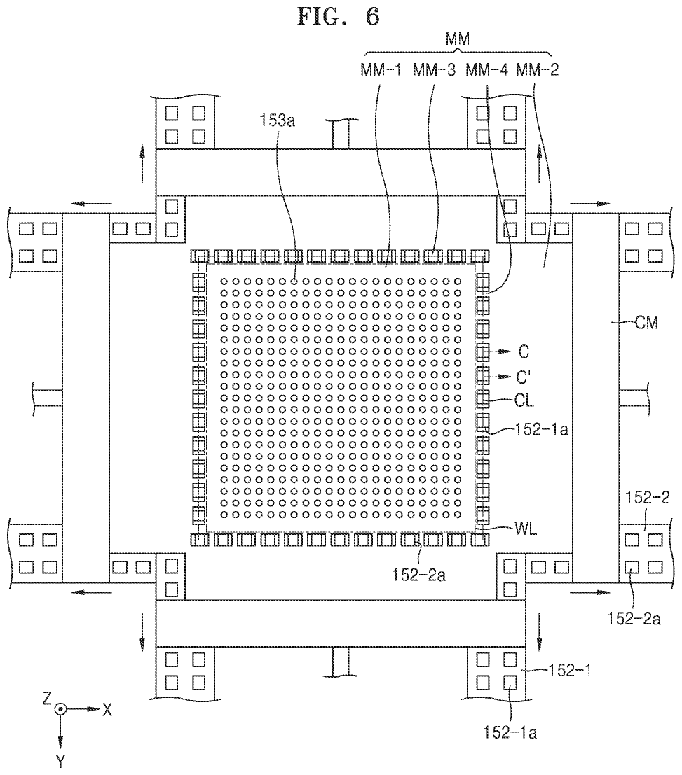

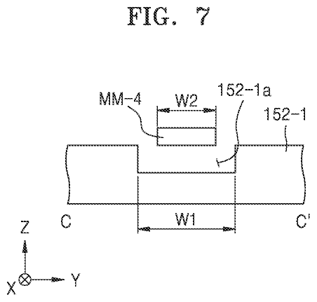

FIG. 5 is a schematic front view of an apparatus 200 for manufacturing a mask assembly according to an embodiment. FIG. 6 is a schematic plan view of a method of manufacturing the mask assembly 150 shown in FIG. 1. FIG. 7 is a schematic cross-sectional view of the manufacturing method, taken along line C-C′ of FIG. 6.

Referring to FIGS. 5 to 7, the apparatus 200 for manufacturing a mask assembly may include a first support 210, a second support 220, a linear driver 230, a gantry 240, a stage 250, a clamp unit CM, a linear motion unit 260, a vision unit 270, and a laser irradiation unit 280.

The first support 210 may be disposed on the ground, an external structure, or the like. The second support 220 may be connected to the first support 210. For example, the linear driver 230 may be disposed on a top surface (or upper surface) of the second support 220.

The linear driver 230 may be disposed on the second support 220 to move (e.g., linearly move) the gantry 240. For example, the linear driver 230 may have various forms. For example, the linear driver 230 may include a linear motor connecting the second support 220 and the gantry 240 to each other. For example, a drive rail may be disposed on one of the second support 220 and the gantry 240, and a block moving relative to the drive rail according to an operation of the drive rail may be disposed on the other one of the second support 220 and the gantry 240. In another example, the linear driver 230 may include a block connected to the gantry 240, a ball screw connected to the block, and a motor rotating a screw of the ball screw. In another example, the linear driver 230 may be disposed on the second support 220 and may include a cylinder connected to the gantry 240 and a linear motion guide disposed between the gantry 240 and the second support 220. The linear driver 230 is not limited to the above description, and may include any device and structure disposed between the second support 220 and the gantry 240 to move (e.g., linearly move) the gantry 240.

The gantry 240 may be connected to the linear driver 230 to move (e.g., linearly move) according to an operation of the linear driver 230. For example, the gantry 240 may support the linear motion unit 260.

The stage 250 may be connected to the first support 210. For example, the mask frame 151 may be mounted on the stage 250. For example, the stage 250 may move up and down.

The clamp unit CM may be disposed on the stage 250 to grip and draw a mask sheet mother material MM. For example, the clamp unit CM may be disposed on each portion of the stage 250 to move (e.g., move up and down or linearly move). For example, the clamp unit CM may include clamp units CM.

The linear motion unit 260 may be disposed on the gantry 240 to move (e.g., linearly move) along the gantry 240. For example, a separate driver may be disposed between the linear motion unit 260 and the gantry 240. For example, the driver may be in the same or similar form as the linear driver 230 described above.

The vision unit 270 may be disposed on the linear motion unit 260 to move together with the linear motion unit 260. For example, the vision unit 270 may include a camera and may capture the mask sheet mother material MM, a support member, and a mask frame. Thus, it may be checked whether the mask sheet mother material MM is disposed in the correct position.

The laser irradiation unit 280 may be disposed on the linear motion unit 260 to move together according to movement of the linear motion unit 260. For example, the laser irradiation unit 280 may attach the mask sheet mother material MM on a support member or cut a portion of the mask sheet mother material MM.

During the above operation of the apparatus 200 for manufacturing a mask assembly, a mask frame on which the first support member 152-1 and the second support member 152-2 are disposed may be disposed on the stage 250, and the mask sheet mother material MM may be fixed to each clamp unit CM. For example, the clamp unit CM may grip and draw the mask sheet mother material MM in four directions.

For example, the mask sheet mother material MM may include a body portion MM-1, a wing portion MM-2, an incision portion MM-3, and a rib portion MM-4. The body portion MM-1 may form the mask sheet 153, and the opening (e.g., hole) 153a may be arranged in the body portion MM-1. The wing portion MM-2 may protrude from a side surface of the body portion MM-1 and may be a region gripped by the clamp unit CM. The incision portion MM-3 may be arranged between the wing portion MM-2 and the body portion MM-1. For example, the incision portion MM-3 may be in the form of a hole (or an opening) and may include incision portions MM-3 such as a plurality of holes (or openings). For example, the incision portions MM-3 may be arranged in a line in a direction. For example, the incision portions MM-3 may be spaced apart from each other by a certain distance and may be arranged along the edge portion of the body portion MM-1. The rib portion MM-4 may be arranged between incision portions MM-3 adjacent to each other. For example, the rib portion MM-4 may overlap the first groove 152-1a or the second groove 152-2a in a plan view, according to a position thereof.

For example, a second width W2 of the rib portion MM-4 measured in a first direction or a second direction may be smaller than a first width W1, which is a width of the first groove 152-1a or a width of the second groove 152-2a measured in the same direction. For example, the second width W2 of the rib portion MM-4 may be measured in a direction perpendicular to a direction from the body portion MM-1 toward the wing portion MM-2.

As described above, positions of the mask sheet 153, the first support member 152-1, the second support member 152-2, and the mask frame 151 may be identified by the vision unit 270 after the mask sheet mother material MM is disposed, and thus, a position of the mask sheet 153 or a position of the mask frame 151 may be adjusted. For example, in case that a position of the mask sheet 153 is adjusted, a position of each clamp unit CM may be changed. In case that a position of the mask frame 151 is changed, a position of the mask frame 151 may be finely adjusted by the stage 250. For example, each of the clamp unit CM and the stage 250 may be provided with a separate driver for the above fine adjustment.

In case that a position of the mask sheet 153 or a position of the mask frame 151 is adjusted as described above and determined as corresponding to a previously set position, the mask sheet mother material MM may be welded to the first support member 152-1 and the second support member 152-2 by the laser irradiation unit 280. For example, the laser irradiation unit 280 may supply a laser to the mask sheet mother material MM in case that the laser irradiation unit 280 moves around the body portion MM-1 according to movement of the linear motion unit 260 and movement of the gantry 240.

For example, in case that a laser is irradiated, the mask sheet mother material MM may be fixed on the first support member 152-1 and the second support member 152-2. For example, the laser may be irradiated along a virtual welding line WL disposed around the body portion MM-1. For example, welding points WP that are formed may not be connected to each other, and welding points WP spaced apart from each other may be formed. For example, the welding points WP may be arranged in various forms. For example, some of the welding points WP may be disposed on the welding line WL as shown in FIG. 6, and some of the welding points WP may be spaced apart from each other on another welding line disposed on an outer or inner side of the welding line WL shown in FIG. 6. For example, welding points WP disposed on different welding lines from each other may be arranged in a line with each other in a first direction or a second direction. In another example, welding points WP disposed on different welding lines from each other may not be arranged in a line with each other in a first direction or a second direction. For example, welding points WP disposed on different welding lines from each other may be arranged in a zigzag pattern.

After the mask sheet mother material MM is attached on the first support member 152-1 and the second support member 152-2 as described above, the laser irradiation unit 280 may be arranged so as to correspond to the rib portion MM-4, and a laser may be irradiated on the rib portion MM-4. For example, the laser irradiation unit 280 may irradiate a laser on the rib portion MM-4, thereby cutting the rib portion MM-4. For example, the laser irradiation unit 280 may move along a cutting line CL of FIG. 6. For example, the laser irradiation unit 280 may irradiate a laser on the rib portion MM-4 during the same or different time period as when forming a welding point WP at the same intensity as when forming a welding point WP. In another example, the laser irradiation unit 280 may irradiate a laser on the rib portion MM-4 during the same or different time period as when forming a welding point WP at a different intensity from when forming a welding point WP.

For example, positions of the mask sheet 153 and the mask frame 151 may not be aligned with each other before a laser is irradiated on the rib portion MM-4 with the laser irradiation unit 280. For example, the laser irradiation unit 280 may cut the rib portion MM-4 with the laser used to form a welding point WP, and thus, a position of the mask sheet 153 and a position of the mask frame 151 may not be additionally checked by the vision unit 270.

For example, the rib portion MM-4 may be disposed above the first groove 152-la of the first support member 152-1 or the second groove 152-2a of the second support member 152-2, and thus, burrs (or bent edge) generated in case that the rib portion MM-4 is cut with a laser may be prevented from being accumulated on the first support member 152-1 or the second support member 152-2. For example, as described above, the second width W2 may be smaller than the first width W1, and thus, burrs (or bent edge) generated from a side surface of the rib portion MM-4 may also be inserted (e.g., completely inserted) into the first groove 152-la or the second groove 152-2a to reduce the mask sheet 153 from being poorly attached on the first support member 152-1 or the second support member 152-2 due to burrs (or bent edge).

For example, each wing portion MM-2 may be separated from the body portion MM-1. For example, the body portion MM-1 may have a shape of the mask sheet 153 shown in FIG. 1.

For example, a method of manufacturing a mask assembly may reduce the time and the cost required to manufacture the mask assembly by performing a welding process and a cutting process with the same device. For example, the apparatus 200 for manufacturing a mask assembly may use the laser irradiation unit 280 used in a welding process to separate the wing portion MM-2 from the body portion MM-1 without having a separate laser irradiation unit, thereby reducing installation space, and increasing the convenience of use due to a simple structure.

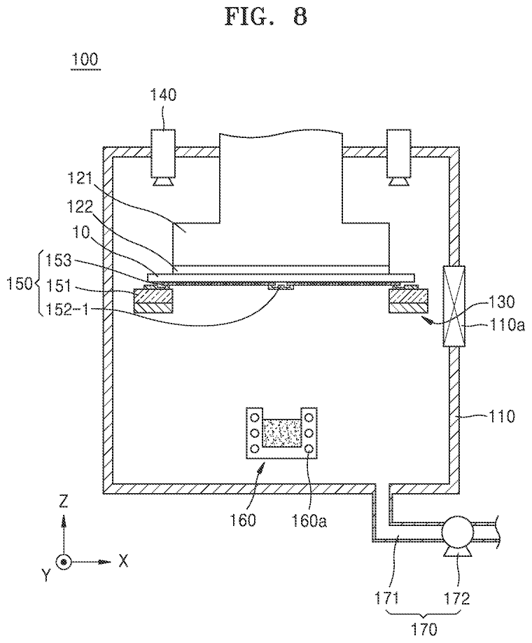

FIG. 8 is a schematic cross-sectional view of an apparatus 100 for manufacturing a display device according to an embodiment.

Referring to FIG. 8, the apparatus 100 for manufacturing a display device may include a chamber 110, the mask assembly 150, a support 130, a deposition source 160, a vision unit 140, a pressure adjuster 170, and contact units 121 and 122.

The chamber 110 may include a space therein and may have an opened portion. A gate valve 110a may be installed in the opened portion of the chamber 110 to open or close the opened portion.

The mask assembly 150 may include the mask frame 151, the mask sheet 153, the first support member 152-1, and the second support member 152-2. For example, the mask frame 151, the mask sheet 153, the first support member 152-1, and the second support member 152-2 are the same as or similar to those described above, and thus, a detailed description thereof is omitted for descriptive convenience.

The mask frame 151 may be mounted on the support 130. For example, the support 130 may be fixed in the chamber 110. For example, the support 130 may adjust relative positions of a substrate 10 and the mask assembly 150 by changing a position of the mask assembly 150. In another example, the support 130 may include a carrier for gripping and transporting the mask assembly 150 and the substrate 10. For example, the support 130 may grip the mask assembly 150 and the substrate 10 in the way shown in FIG. 8 in a space different from the chamber 110 and move the same into the chamber 110. Hereinafter, a case in which the support 130 supports only the mask assembly 150 will be described for descriptive convenience.

The deposition source 160 may face the mask assembly 150. For example, the deposition source 160 may be fixed in the chamber 110. In another example, the deposition source 160 may be movable in the chamber 110. However, a case in which the deposition source 160 is fixed in the chamber 110 will be described below for descriptive convenience.

A deposition material may be received in the deposition source 160. For example, a heater 160a for applying heat to the deposition material may be arranged in the deposition source 160.

The vision unit 140 may be installed in the chamber 110 to capture (or sense) positions of the substrate 10 and the mask assembly 150. For example, the vision unit 140 may transmit a captured image to a controller. The controller may align the substrate 10 and the mask assembly 150 with each other by the support 130, based on the positions of the substrate 10 and the mask assembly 150. In another example, the controller may adjust a position of the mask assembly 150 by capturing a position of the mask assembly 150 by the vision unit 140 before the substrate 10 is inserted into the chamber 110 and may arrange the substrate 10 so as to correspond to (or overlap) a position of the mask assembly 150. For example, the substrate 10 may be disposed on the mask assembly 150 through a robot arm or the like outside the chamber 110. In another example, the controller may align positions of the deposition source 160 and the mask assembly 150 with each other, based on positions of the substrate 10 and the mask assembly 150 captured by the vision unit 140.

The pressure adjuster 170 may be connected to the chamber 110 to discharge gas inside the chamber 110 to the outside. For example, the pressure adjuster 170 may include a connection pipe 171 connected to the chamber 110 and a pressure adjustment pump 172 installed in the connection pipe 171. According to an operation of the pressure adjustment pump 172, pressure inside the chamber 110 may be maintained at atmospheric pressure or in a vacuum state.

The contact units 121 and 122 may contact the substrate 10 and may press the substrate 10 and the mask assembly 150 into close contact with each other. For example, the contact units 121 and 122 may adjust a temperature of the substrate 10 by contacting or approaching the substrate 10. For example, the contact units 121 and 122 may include a magnetic force portion 121 for providing a magnetic force to the mask assembly 150, and a cooling plate 122 disposed between the magnetic force portion 121 and the substrate 10. For example, the cooling plate 122 may contact the substrate 10, and may lower a temperature of the substrate 10 in case that a deposition material is deposited on the substrate 10.

According to the above operation method of the apparatus 100 for manufacturing a display device, the mask assembly 150 may be inserted from the outside into the chamber 110. The mask assembly 150 may be mounted on the support 130. For example, the mask assembly 150 may be transferred into the chamber 110 from outside the chamber 110 by a robot arm separately provided outside the chamber 110. In another example, the mask assembly 150 may be connected to the chamber 110 and may be supplied from a separate chamber storing the mask assembly 150.

In case that the above process is completed, the substrate 10 may be disposed on the mask assembly 150 by a robot arm from outside the chamber 110. For example, positions of the substrate 10 and the mask assembly 150 may be adjusted based on an image captured by the vision unit 140.

In another example, as described above, the substrate 10 and the mask assembly 150 may be disposed on a carrier outside the chamber 110, and positions thereof may be fixed after the carrier is transferred from outside the chamber 110 into the inside.

In case that the above process is completed, the contact units 121 and 122 may contact one surface of the substrate 10 or may be in close contact with one surface of the substrate 10 as much as possible. For example, the support 130 or the contact units 121 and 122 may move (e.g., linearly move). In an embodiment, the support 130 may move up and press the substrate into contact with the contact units 121 and 122. In another example, the contact units 121 and 122 may move down and contact the substrate 10.

For example, the contact units 121 and 122 may press the substrate 10 into close contact with the mask assembly 150. For example, a method of pressing the substrate 10 into close contact with the mask assembly 150 may include a method in which the contact units 121 and 122 apply force to the substrate 10 toward the mask assembly 150 and a method in which the mask assembly 150 is drawn toward the contact units 121 and 122 by providing a magnetic force to the mask assembly 150.

For example, in case that the mask sheet 153 protrudes toward the substrate 10 at a portion coupled to at least one of the first support member 152-1 and the second support member 152-2, excessive force may be applied to the substrate 10, causing damage to the substrate 10. However, the end portion of the mask sheet 153 may not be arranged at a boundary area of the first groove 152-la of the first support member 152-1 or the second groove 152-2a of the second support member 152-2 in a plan view but may overlap the first groove 152-la of the first support member 152-1 or the second groove 152-2a of the second support member 152-2 in a plan view and thus may be in the form of a cantilever. For example, the end portion of the mask sheet 153 may have a structure that is capable for being freely shaken, and accordingly, in case that in contact with the substrate 10, the end portion of the mask sheet 153 may be deformed rather than continuously apply force to the substrate 10.

For example, damage to the substrate 10 may be prevented by reducing force applied to the substrate 10 by the end portion of the mask sheet 153.

In case that the above process is completed, the heater 160a may operate to vaporize or sublimate a deposition material, and the deposition material may pass through the mask assembly 150 and be deposited on the substrate 10. For example, the deposition material described above may form at least one of an emission layer and an organic functional layer to be described below on the substrate 10.

The cooling plate 122 may operate to lower a temperature of the substrate 10, thereby preventing the deposition material from being out of place after being deposited on the substrate 10. For example, the pressure adjustment pump 172 may operate to discharge a deposition material inside the chamber 110 to the outside.

Accordingly, the apparatus 100 for manufacturing a display device and the method of manufacturing a display device may prevent damage to the substrate 10 during deposition of a deposition material on the substrate 10. The apparatus 100 for manufacturing a display device and the method of manufacturing a display device may prevent damage to the substrate 10 during deposition, thereby improving product quality and reducing manufacturing defects.

The apparatus 100 for manufacturing a display device and the method of manufacturing a display device may prevent reduction of the lifespan of a manufactured display device caused by damage to the substrate 10.

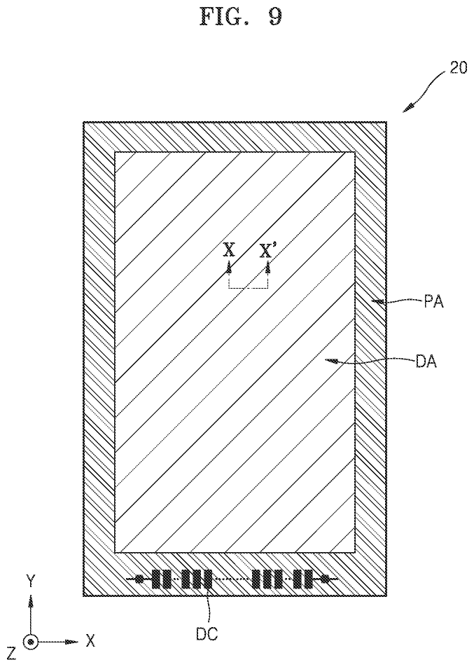

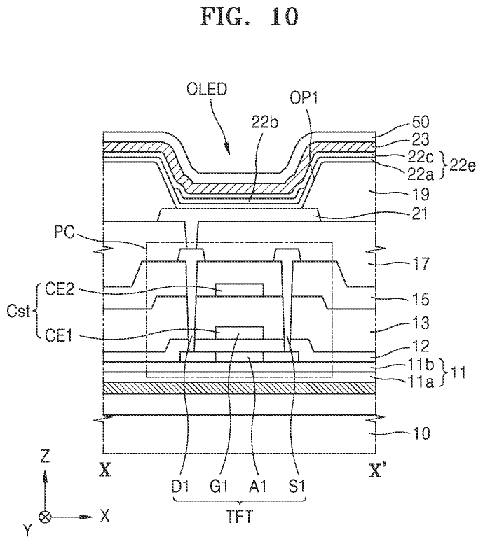

FIG. 9 is a schematic plan view of a display device 20 according to an embodiment. FIG. 10 is a cross-sectional view of the display device 20, taken along line X-X′ of FIG. 9.

Referring to FIGS. 9 and 10, the display device 20 may be a light-emitting display panel including a light-emitting element. For example, the display device 20 may be an organic light-emitting display panel using an organic light-emitting diode including an organic emission layer, a micro light-emitting diode (LED) display panel using a micro LED, a quantum-dot light-emitting display panel using a quantum-dot light-emitting diode including a quantum-dot emission layer, or an inorganic light-emitting display panel using an inorganic light-emitting diode including an inorganic semiconductor.

The display device 20 may be a flexible display panel having flexibility and readily bendable, foldable, or rollable. Examples of the display device 20 may include a foldable display panel that is folded or unfolded, a curved display panel in which a display surface is curved, a bent display panel in which an area other than a display surface is bent, a rollable display panel that is rolled or spread, and a stretchable display panel.

The display device 20 may be a transparent display panel which is transparent such that an object or background arranged on a bottom surface of the display device 20 may be viewed through a top surface (or upper surface) of the display device 20. In another example, the display device 20 may be a reflective display panel which may reflect an object or background of a top surface (or upper surface) of the display device 20.

The display device 20 may include a display area DA in which an image is displayed and a peripheral area PA surrounding the display area DA. A separate driving circuit DC, a pad, etc. may be arranged in the peripheral area PA.

The display device 20 may have the substrate 10, a buffer layer 11, a circuit layer, and a display element layer stacked on one another.

The substrate 10 may include an insulating material, such as glass, quartz, or polymer resin. The substrate 10 may be a rigid substrate or a flexible substrate which is bendable, foldable, or rollable.

The buffer layer 11 may be positioned on the substrate 10 to decrease or prevent penetration of a foreign material, moisture, or external air from below the substrate 10 and may provide a flat surface on the substrate 10. The buffer layer 11 may include an inorganic material, such as oxide or nitride, an organic material, or an organic-inorganic compound, and may have a single-layer structure or a multi-layer structure including an inorganic material and an organic material. A barrier layer that prevents penetration (or permeation) of external air may be further between the substrate 10 and the buffer layer 11. In some embodiments, the buffer layer 11 may include silicon oxide (SiO₂) or silicon nitride (SiNₓ). The buffer layer 11 may have a first buffer layer 11a and a second buffer layer 11b stacked on each other.

The circuit layer may be disposed on the buffer layer 11 and may include a pixel circuit PC, a first gate insulating layer 12, a second gate insulating layer 13, an interlayer insulating layer 15, and a planarization layer 17. The pixel circuit PC may include a thin-film transistor TFT and a storage capacitor Cst.

The thin-film transistor TFT may be disposed on the buffer layer 11. The thin-film transistor TFT may include a first semiconductor layer A1, a first gate electrode G1, a first source electrode S1, and a first drain electrode D1. The thin-film transistor TFT may be connected to an organic light-emitting diode OLED to drive the organic light-emitting diode OLED.

The first semiconductor layer A1 may be disposed on the buffer layer 11 and may include polysilicon. In another example, the first semiconductor layer A1 may include amorphous silicon. In another example, the first semiconductor layer A1 may include oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region and source and drain regions doped with impurities (or dopants).

The first gate insulating layer 12 may cover the first semiconductor layer A1. The first gate insulating layer 12 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂) The first gate insulating layer 12 may have a single-layer structure or a multi-layer structure including the above-described inorganic insulating material.

The first gate electrode G1 may be disposed on the first gate insulating layer 12 and overlap the first semiconductor layer A1. The first gate electrode G1 may include molybdenum (Mo), aluminum (Al), copper (Cu), titanium (Ti), etc. and may include a single layer or layers. As an example, the first gate electrode G1 may include a single Mo layer.

The second gate insulating layer 13 may cover the first gate electrode G1. The second gate insulating layer 13 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ such as ZnO and/or ZnO₂) The second gate insulating layer 13 may have a single-layer structure or a multi-layer structure including the above-described inorganic insulating material.

A first upper electrode CE2 of the storage capacitor Cst may be disposed on the second gate insulating layer 13.

In the display area DA, the first upper electrode CE2 may overlap the first gate electrode G1 therebelow. The first gate electrode G1 and the first upper electrode CE2 overlapping each other with the second gate insulating layer 13 therebetween may form the storage capacitor Cst. The first gate electrode G1 may be a first lower electrode CE1 of the storage capacitor Cst.

The first upper electrode CE2 may include aluminum (Al), platinum (Pt), palladium (Pd), silver (Ag), magnesium (Mg), gold (Au), nickel (Ni), neodymium (Nd), iridium (Jr), chromium (Cr), calcium (Ca), molybdenum (Mo), titanium (Ti), tungsten (W) and/or copper (Cu), and may have a single-layer structure or a multi-layer structure including the above-described material.

The interlayer insulating layer 15 may cover the first upper electrode CE2. The interlayer insulating layer 15 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ such as ZnO and/or ZnO₂) The interlayer insulating layer 15 may have a single-layer structure or a multi-layer structure including the above-described inorganic insulating material.

The first source electrode S1 and the first drain electrode D1 may be disposed on the interlayer insulating layer 15. The first source electrode S1 and the first drain electrode D1 may each include a conductive material including molybdenum (Mo), aluminum (Al), copper (Cu), titanium (Ti), etc. and may have a multi-layer structure or a single-layer structure including the above-described material. As an example, the first source electrode S1 and the first drain electrode D1 may have a multi-layer structure of Ti/Al/Ti.

The planarization layer 17 may cover the first source electrode S1 and the first drain electrode D1. The planarization layer 17 may have a flat top surface (or flat upper surface) such that a pixel electrode 21 disposed thereon may be flat.

The planarization layer 17 may include an organic material or an inorganic material and may have a single-layer structure or a multi-layer structure. The planarization layer 17 may include a general commercial polymer, such as benzocyclobutene (BCB), polyimide, hexamethyldisiloxane (HMDSO), poly(methyl methacrylate) (PMMA), or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer. The planarization layer 17 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ such as ZnO and/or ZnO₂). In case that the planarization layer 17 is formed, a layer may be formed, and chemical and mechanical polishing may be performed on a top surface (or upper surface) of the layer to provide a flat top surface (or flat upper surface).

The planarization layer 17 may include a via hole exposing one of the first source electrode S1 and the first drain electrode D1 of the thin-film transistor TFT, and the pixel electrode 21 may be electrically connected to the thin-film transistor TFT by contacting the first source electrode S1 or the first drain electrode D1 through the via hole.

The pixel electrode 21 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective layer including silver (Ag), magnesium (Mg), aluminum (Al), platinum (Pt), palladium (Pd), gold (Au), nickel (Ni), neodymium (Nd), iridium (Jr), chromium (Cr), or a compound thereof. For example, the pixel electrode 21 may have a structure including layers formed of ITO, IZO, ZnO, or In₂O₃ on/under the above-described reflective layer. For example, the pixel electrode 21 may have a stack structure of ITO/Ag/ITO.

A pixel-defining layer 19 may cover edge portions of the pixel electrode 21 on the planarization layer 17 and may include a first opening OP1 exposing a central portion of the pixel electrode 21. An emission area of the organic light-emitting diode OLED, for example, a size and shape of a sub-pixel may be defined by the first opening OP1.

The pixel-defining layer 19 may prevent an arc, etc. from occurring at the edge portions of the pixel electrode 21 by increasing a distance between the edge portions of the pixel electrode 21 and an opposite electrode 23 above the pixel electrode 21. The pixel-defining layer 19 may include an organic insulating material, such as polyimide, polyamide, acrylic resin, benzocyclobutene (BCB), hexamethyldisiloxane (HMDSO), phenolic resin, etc., and may be formed by a method, such as a spin coating process.

An emission layer 22b may be arranged in the first opening OP1 of the pixel-defining layer 19 to correspond to each pixel electrode 21. The emission layer 22b may include a polymer material or a low-molecular weight material and may emit red light, green light, blue light, or white light.

An organic functional layer 22e may be disposed on and/or under the emission layer 22b. The organic functional layer 22e may include a first functional layer 22a and/or a second functional layer 22c. The first functional layer 22a or the second functional layer 22c may be omitted.

The first functional layer 22a may be disposed under the emission layer 22b. The first functional layer 22a may have a single-layer structure or a multi-layer structure including an organic material. The first functional layer 22a may be a hole transport layer (HTL) that is a single layer. In another example, the first functional layer 22a may include a hole injection layer (HIL) and a hole transport layer (HTL). The first functional layer 22a may be integral to correspond to organic light-emitting diodes OLED included in the display area DA.

The second functional layer 22c may be disposed on the emission layer 22b. The second functional layer 22c may have a single-layer structure or a multi-layer structure including an organic material. The second functional layer 22c may include an electron transport layer (ETL) and/or an electron injection layer (EIL). The second functional layer 22c may be integral to correspond to the organic light-emitting diodes OLED included in the display area DA.

The opposite electrode 23 may be disposed on the second functional layer 22c. The opposite electrode 23 may include a conductive material having a low work function. For example, the opposite electrode 23 may include a transparent layer (or a semi-transparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another example, the opposite electrode 23 may further include a layer formed of such as ITO, IZO, ZnO, or In₂O₃, on a transparent layer (or a semi-transparent layer) including the above-described material. The opposite electrode 23 may be integral to correspond to the organic light-emitting diodes OLED included in the display area DA.

The pixel electrode 21, the emission layer 22b, the organic functional layer 22e, and the opposite electrode 23 in the display area DA may form the organic light-emitting diode OLED.

A cover layer 50 may be formed on the opposite electrode 23 and may include an organic material. The cover layer 50 may protect the opposite electrode 23 and may also increase light extraction efficiency. The cover layer 50 may include an organic material having a higher refractive index than the opposite electrode 23. In another example, the cover layer 50 may have layers of different refractive indices stacked on each other. For example, the cover layer 50 may include a high refractive index layer/a low refractive index layer/a high refractive index layer. For example, a refractive index of the high refractive index layer may be about 1.7 or greater, and a refractive index of the low refractive index layer may be about 1.3 or less.

The cover layer 50 may additionally include lithium fluoride (LiF). In another example, the cover layer 50 may additionally include an inorganic insulating material, such as silicon oxide (SiO₂) and/or silicon nitride (SiNₓ). The cover layer 50 may be omitted in some cases. However, a case in which the cover layer 50 is disposed on the opposite electrode 23 will be described below for descriptive convenience.

For example, the display device 20 may include a thin-film encapsulation layer shielding the cover layer 50.

The thin-film encapsulation layer may be disposed on the cover layer 50 to contact (e.g., directly contact) the cover layer 50. For example, the thin-film encapsulation layer may cover portions of the display area DA and the peripheral area PA to prevent the penetration (or permeation) of external moisture and oxygen. The thin-film encapsulation layer may include at least one organic encapsulation layer and at least one inorganic encapsulation layer. Hereinafter, a case in which the thin-film encapsulation layer includes a first inorganic encapsulation layer, an organic encapsulation layer, and a second inorganic encapsulation layer sequentially stacked on the cover layer 50 will be described for descriptive convenience.

For example, the first inorganic encapsulation layer may cover the opposite electrode 23 and may include silicon oxide, silicon nitride and/or silicon oxynitride. Because the first inorganic encapsulation layer is formed along a structure thereunder, a top surface (or upper surface) of the first inorganic encapsulation layer may not be flat. The organic encapsulation layer may cover the first inorganic encapsulation layer, and unlike the first inorganic encapsulation layer, a top surface (or upper surface) of the organic encapsulation layer may be substantially flat. For example, a top surface (or upper surface) of the organic encapsulation layer may be substantially flat at a portion thereof corresponding to the display area DA. The organic encapsulation layer may include one or more materials selected from the group including polyethylene terephthalate, polyethylene naphthalate, polycarbonate, polyimide, polyethylene sulfonate, polyoxymethylene, polyarylate, and hexamethyldisiloxan (HMDSO). The second inorganic encapsulation layer may cover the organic encapsulation layer and may include silicon oxide, silicon nitride and/or silicon oxynitride.

A touchscreen layer may be disposed on the thin-film encapsulation layer.

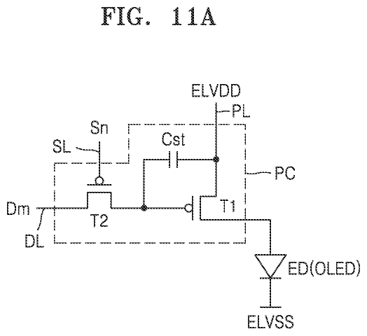

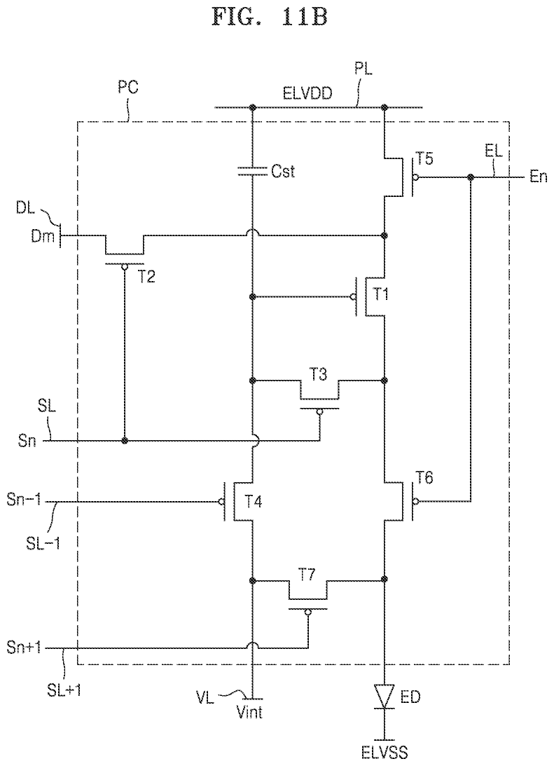

FIGS. 11A and 11B are schematic diagrams of equivalent circuits of a sub-pixel included in the display device 20 shown in FIG. 9.

Referring to FIGS. 11A and 11B, the pixel circuit PC may be connected to a light-emitting element ED to implement emission of sub-pixels. The pixel circuit PC may include a driving thin-film transistor T1, a switching thin-film transistor T2, and the storage capacitor Cst. The switching thin-film transistor T2 may be connected to a scan line SL and a data line DL and may transmit a data signal Dm input through the data line DL to the driving thin-film transistor T1 according to a scan signal Sn input through the scan line SL.

The storage capacitor Cst may be connected to the switching thin-film transistor T2 and a driving voltage line PL and may store a voltage corresponding to a difference between a voltage received from the switching thin-film transistor T2 and a driving voltage ELVDD supplied to the driving voltage line PL.

The driving thin-film transistor T1 may be connected to the driving voltage line PL and the storage capacitor Cst and may control a driving current flowing through the light-emitting element ED from the driving voltage line PL in response to a voltage stored in the storage capacitor Cst. The light-emitting element ED may emit light having certain brightness according to the driving current.

Although FIG. 11A shows a case in which the pixel circuit PC includes two thin-film transistors and one storage capacitor, one or more embodiments are not limited thereto.

Referring to FIG. 11B, the pixel circuit PC may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 11B shows a case in which signal lines, e.g., the scan line SL, a previous scan line SL−1, a next scan line SL+1, an emission control line EL, the data line DL, an initialization voltage line VL, and the driving voltage line PL are provided for each pixel circuit PC, one or more embodiments are not limited thereto. In another example, at least one of signal lines, e.g., the scan line SL, the previous scan line SL−1, the next scan line SL+1, the emission control line EL, the data line DL, and/or the initialization voltage line VL may be shared by neighboring pixel circuits.

A drain electrode of the driving thin-film transistor T1 may be electrically connected to the light-emitting element ED through the emission control thin-film transistor T6. The driving thin-film transistor T1 may receive the data signal Dm according to a switching operation of the switching thin-film transistor T2 and supply a driving current to the light-emitting element ED.

A gate electrode of the switching thin-film transistor T2 may be connected to the scan line SL, and a source electrode of the switching thin-film transistor T2 may be connected to the data line DL. A drain electrode of the switching thin-film transistor T2 may be connected to a source electrode of the driving thin-film transistor T1 and may also be connected to the driving voltage line PL through the operation control thin-film transistor T5.

The switching thin-film transistor T2 may be turned on according to the scan signal Sn received through the scan line SL and perform a switching operation for transferring the data signal Dm transmitted through the data line DL to the source electrode of the driving thin-film transistor T1.

A gate electrode of the compensation thin-film transistor T3 may be connected to the scan line SL. A source electrode of the compensation thin-film transistor T3 may be connected to the drain electrode of the driving thin-film transistor T1 and may also be connected to a pixel electrode of the light-emitting element ED through the emission control thin-film transistor T6. A drain electrode of the compensation thin-film transistor T3 may be connected to an electrode of the storage capacitor Cst, a source electrode of the first initialization thin-film transistor T4, and a gate electrode of the driving thin-film transistor T1. The compensation thin-film transistor T3 may be turned on according to the scan signal Sn received through the scan line SL and diode-connect the driving thin-film transistor T1 by connecting the gate electrode and the drain electrode of the driving thin-film transistor T1 to each other.

A gate electrode of the first initialization thin-film transistor T4 may be connected to the previous scan line SL−1. A drain electrode of the first initialization thin-film transistor T4 may be connected to the initialization voltage line VL. The source electrode of the first initialization thin-film transistor T4 may be connected to an electrode of the storage capacitor Cst, the drain electrode of the compensation thin-film transistor T3, and the gate electrode of the driving thin-film transistor T1. The first initialization thin-film transistor T4 may be turned on according to a previous scan signal Sn−1 received through the previous scan line SL−1 and perform an initialization operation for initializing a voltage of the gate electrode of the driving thin-film transistor T1 by transferring an initialization voltage Vint to the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. As the operation control thin-film transistor T5 and the emission control thin-film transistor T6 are simultaneously turned on according to an emission control signal En received through the emission control line EL, the driving voltage ELVDD may be transferred to the light-emitting element ED, and a driving current may flow through the light-emitting element ED.

A gate electrode of the second initialization thin-film transistor T7 may be connected to the next scan line SL+1. A source electrode of the second initialization thin-film transistor T7 may be connected to the pixel electrode of the light-emitting element ED. A drain electrode of the second initialization thin-film transistor T7 may be connected to the initialization voltage line VL. The second initialization thin-film transistor T7 may be turned on according to a next scan signal Sn+1 received through the next scan line SL+1 and initialize the pixel electrode of the light-emitting element ED.

Although FIG. 11B shows a case in which the first initialization thin-film transistor T4 and the second initialization thin-film transistor T7 are connected to the previous scan line SL−1 and the next scan line SL+1, respectively, one or more embodiments are not limited thereto. In another example, both of the first initialization thin-film transistor T4 and the second initialization thin-film transistor T7 may be connected to the previous scan line SL−1 and driven according to the previous scan signal Sn−1.

The other electrode of the storage capacitor Cst may be connected to the driving voltage line PL. An electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the light-emitting element ED may receive a common voltage ELVSS. The light-emitting element ED may receive a driving current from the driving thin-film transistor T1 and emit light.

The pixel circuit PC is not limited to the number of thin-film transistors and storage capacitors and the circuit design described with reference to FIGS. 11A and 11B, and the number of thin-film transistors and storage capacitors and the circuit design may be variously modified.

A mask assembly, an apparatus for manufacturing a display device, and a method of manufacturing a display device according to embodiments may provide a display device including an emission layer having a fine pattern. A method of manufacturing a mask assembly according to embodiments may provide a mask assembly with reduced deformation and may be capable of rapid manufacturing of a mask assembly.

For example, a mask assembly, an apparatus for manufacturing a display device, and a method of manufacturing a display device according to embodiments may prevent damage to a substrate during the manufacture of a display device. A method of manufacturing a mask assembly according to embodiments may be capable of rapid and precise manufacturing of a mask assembly. A method of manufacturing a mask assembly according to embodiments may provide a mask assembly with reduced deformation.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A mask assembly comprising:
a mask frame comprising an opening region;
a support member disposed on the mask frame to divide the opening region into at least two; and
a mask sheet disposed on the support member to overlap the opening region, the mask sheet comprising uneven edge portions and a plurality of holes.

2. The mask assembly of claim 1, wherein the mask sheet is fixed to the support member in a tensioned state.

3. The mask assembly of claim 1, wherein the support member comprises a groove overlapping a protruding portion of the uneven edge portions of the mask sheet.

4. The mask assembly of claim 3, wherein the groove comprises a plurality of grooves spaced apart from each other.

5. The mask assembly of claim 3, wherein the groove has a line shape in a longitudinal direction of the support member.

6. The mask assembly of claim 3, wherein a width of the protruding portion of the uneven edge portions of the mask sheet in a longitudinal direction of the support member is smaller than a width of the groove in the support member in the longitudinal direction of the support member.

7. The mask assembly of claim 3, wherein
the mask sheet is fixed to the support member by a welding process, and
the support member comprises a welding groove overlapping a welding point formed during the welding process and having a depth smaller than a depth of the groove.

8. The mask assembly of claim 7, wherein the depth of the welding groove is about 20% or less of a thickness of the support member.

9. The mask assembly of claim 1, wherein
the mask sheet is fixed to the support member by a welding process, and
a welding point formed by the welding process is disposed on an inner side of the uneven edge portions of the mask sheet.

10. The mask assembly of claim 9, wherein the support member comprises a welding groove overlapping the welding point.

11. The mask assembly of claim 10, wherein a depth of the welding groove is about 20% or less of a thickness of the support member.

12. An apparatus for manufacturing a display device, the apparatus comprising:
a chamber;
a mask assembly overlapping a substrate disposed in the chamber; and
a deposition source that supplies a deposition material to the substrate,
wherein the mask assembly is the mask assembly recited in claim 1.

13. A method of manufacturing a mask assembly, the method comprising:
disposing and fixing a support member on a mask frame;
disposing a mask sheet mother material on the support member in a tensioned state;
fixing the mask sheet mother material to the support member by a welding process; and
forming a mask sheet including edge portions in an uneven shape by a cutting process cutting a portion of the mask sheet mother material.

14. The method of claim 13, wherein
the mask sheet mother material includes:
a body portion including a plurality of holes and disposed in a center portion of the mask sheet mother material;
a wing portion protruding from the body portion;
a plurality of incision portions disposed between the body portion and the wing portion, the plurality of incision portions spaced apart from each other and arranged along an edge portion of the body portion; and
at least one rib portion disposed between the plurality of incision portions.

15. The method of claim 14, wherein the support member comprises a groove overlapping the at least one rib portion.

16. The method of claim 15, wherein a width of the at least one rib portion in a direction perpendicular to a longitudinal direction of the at least one rib portion is smaller than a width of the groove in the direction perpendicular to the longitudinal direction of the at least one rib portion.

17. The method of claim 15, wherein the support member comprises a groove overlapping at least a portion of the at least one rib portion in a plan view and having a closed loop shape.

18. The method of claim 14, further comprising forming, in the support member, a welding groove overlapping a welding point at which the mask sheet mother material and the support member are welded to each other.

19. The method of claim 18, wherein a depth of the welding groove is about 20% or less of a thickness of the support member.

20. The method of claim 14, wherein the welding process and the cutting process on the mask sheet mother material are performed by using a same laser.

21. A method of manufacturing a display device, the method comprising:
disposing a substrate and a mask assembly in a chamber; and
supplying a deposition material from a deposition source and depositing the deposition material on the substrate by passing through the mask assembly,
wherein the mask assembly is the mask assembly recited in claim 1.
